(19) United States
(12) Patent Application Publication
(10) Pub. No.: US 2014/0209944 A1
(43) Pub. Date: Jul. 31, 2014

(54) WHITE LED APPARATUS

(71) Applicants: Byeong Cheon Kim, Anseong-si (KR); Yung Ryel Ryu, Irvine, CA (US)

(72) Inventors: Byeong Cheon Kim, Anseong-si (KR); Yung Ryel Ryu, Irvine, CA (US)

(73) Assignee: MOX Inc, Gwangju (KR)

(21) Appl. No.: 14/235,473

(22) PCT Filed: Jul. 24, 2012
(86) PCT No.: PCT/KR2012/005889

§ 371 Date: Mar. 10, 2014

(30) Foreign Application Priority Data
Jul. 28, 2011 (KR) 10-2011-0074859
Apr. 6, 2012 (KR) 10-2012-0036210

(51) Int. Cl. H01L 33/50; H01L 25/075

(52) U.S. Cl. CPC H01L 33/50; H01L 25/0753
USPC 257/89

(57) ABSTRACT

Provided is a white LED device. The white LED device includes a blue LED chip configured to emit blue light of a wavelength range of about 440 nm to 490 nm, a yellow phosphor formed on the blue LED chip and excited by the blue light to emit yellow light of a wavelength range of about 560 nm to 615 nm, a green LED chip configured to emit green light of a wavelength range of about 500 nm to 560 nm, and a red phosphor formed on the green LED chip and excited by the green light to emit red light of a wavelength range of about 615 nm to about 670 nm.

### BACKGROUND OF THE INVENTION

1. Field of the Invention

The present invention relates to a white LED device for use in a full-color display, a back light unit, and an emotional or typical lighting system, and more particularly, to a high-efficiency white LED device for emitting white light with excellent color reproducibility and an excellent color rendering index using an LED chip and a phosphor for emitting light of a specific wavelength range.

2. Description of the Related Art

In general, a light-emitting diode (LED) includes a compound of gallium (Ga), phosphorus (P), and arsenic (As) to emit light when a current is applied thereto. The LED has a longer life than that of a bulb and has a high response speed, and thus has attracted attention as a next-generation light-emitting device of a display apparatus. After the development of red, yellow and green LEDs, a blue LED has been developed by Dr. Shuji Nakamura. Recently, researches have been actively conducted to develop a white LED device using the developed LEDs.

White light, which is similar to natural light, may relieve eyestrain. Therefore, there have been efforts to develop an LED or another type of a light-emitting device that emits white light. As a result of such efforts, cold cathode fluorescent lamps (CCFLs) used in computers, cell phones, projectors, and the like have been gradually replaced with white LED devices. In particular, recently, the white LED devices have been widely applied to back light units (BLUs) of liquid crystal displays (LCDs).

Furthermore, a high energy efficient lighting apparatus has been recently attracted attention in relation to a method of reducing carbon dioxide emission that is one of main causes of global warming. In order to solve the problem of the carbon dioxide emission, there have been efforts to prohibit the use of incandescent bulbs in Europe and the USA. Although inexpensive fluorescent lamps are used instead of the incandescent bulbs, the fluorescent lamps cause pollution by heavy metals such as mercury. Therefore, another alternative lighting apparatus is required. A high-output white LED device is expected to solve such a problem.

The above-described white LED device may be classified into a single-chip type and a multichip type according to a method of generating white light.

The single-chip-type white LED device includes a blue LED chip and a YAG-based yellow phosphor. In detail, an encapsulant containing the YAG-based yellow phosphor surrounds the blue LED chip. According to the single-chip-type white LED device, white light is generated as described below. A part of blue light emitted from the blue LED chip is absorbed by the YAG-based yellow phosphor, and the absorbed blue light is converted to yellow light of a long wavelength through the YAG-based yellow phosphor so as to be emitted. The emitted yellow light is combined with the unabsorbed blue light of the blue LED chip so that white light is generated. However, according to this method, the generated white light has a high color temperature since light of a long wavelength, i.e., red light, has low strength, causing unnatural color reproduction.

Recently, phosphors that emit a large amount of long-wavelength components (particularly, red light) by virtue of blue light excitation have been developed in order to overcome the limitation of the single-chip-type white LED device. White light obtained using such red-light-enhanced phosphors may have an improved correlated color temperature (CCT) and an improved color rendering index (CRI) in comparison with white light obtained using conventional YAG-based phosphors. However, despite this advantage, the white light generated using the red-light-enhanced phosphors has a luminance that is about 50% lower than that of the white light generated using the YAG-based phosphors.

In relation to the above-mentioned limitation, a number of companies have announced that they have developed white LED devices with energy efficiency of at least about 100 lm/W by using blue LED chips and phosphors. However, according to the evaluation of the white LED devices, conducted by the U.S. Department of Energy in 2010, the efficacy of all of the evaluated products ranges from 12 to 67 lm/W, having an average value of 40 lm/W (US DOE Solid-State Lighting CALiPER Program, Summary of Results: Round 10 of Product Testing, May 2010). However, this average value is even lower than the average value of 46 lm/W announced in October 2009 (US DOE Solid-State Lighting CALiPER Program, Summary of Results: Round 9 of Product Testing, October 2009), which indicates that the improvement of the energy efficiency is at a standstill.

According to the multichip-type white LED device, LED chips that emit blue light, green light, and red light (RGB-LED chips) are mounted on a single package so as to generate white light by mixing three primary colors of light. Although the multichip-type white LED device has high efficiency, the manufacturing cost thereof is high and a high-efficiency green LED has not been developed yet. Therefore, the efficacy of the multichip-type white LED device is lower than that of the single-chip-type white LED device.

### SUMMARY OF THE INVENTION

The present invention provides a white LED device for generating white light having a high color rendering index and a low correlated color temperature similar to those of natural light.

The present invention also provides an LED device for improving energy efficiency by minimizing non-luminescent light output loss.

According to an aspect of the present invention, a white LED device includes an LED chip configured to emit light with a peak wavelength range of about 440 nm to about 560 nm, and a phosphor excited by the LED chip to emit light with a peak wavelength range of about 560 nm to about 670 nm.

The white LED device may include a blue LED chip configured to emit blue light, a yellow phosphor formed on the blue LED chip and excited by the blue light to emit yellow light, a green LED chip configured to emit green light, and a red phosphor formed on the green LED chip and excited by the green light to emit red light.

The white LED device may include a bluish green LED chip configured to emit bluish green light, and a red phosphor formed on the bluish green LED chip and excited by the bluish green light to emit red light.

The blue LED chip, the green LED chip, and the bluish green LED chip may have a thin film structure in which a p-type transparent oxide layer is deposited on a p-type nitride layer. The p-type transparent oxide layer may be a p-type ZnO layer doped with arsenic or a p-type BeZnO layer doped with arsenic.

The yellow phosphor may be a YAG-based phosphor or a silicate-based phosphor. The red phosphor may be at least one selected from a sulfide-based phosphor, a nitride-based phosphor, and an oxide-based phosphor.

The yellow phosphor and the red phosphor have a powder form, a pellet form, or a layered structure.

The white LED device may further include a reflective cup accommodating the LED chip and the phosphor, and a package body in which the reflective cup is installed.

The white LED device may further include a PCB substrate on which the LED chip is mounted, wherein the phosphor may be applied onto the LED chip using a mold.

### BRIEF DESCRIPTION OF THE DRAWINGS

The above and other features and advantages of the present invention will become more apparent by describing in detail exemplary embodiments thereof with reference to the attached drawings in which:

FIG. 1 is vertical a cross-sectional view of a white LED device according to a preferred embodiment of the present invention;

FIGS. 2 and 3 are vertical cross-sectional views of a layered structure of the white LED devices according to the preferred embodiment of the present invention;

FIG. 4 is a vertical cross-sectional view of a white LED device according to another preferred embodiment of the present invention;

FIG. 5 is a graph illustrating a white light spectrum of the white LED device according to the preferred embodiment of the present invention; and

FIG. 6 is a graph illustrating a white light spectrum of the white LED device according to the other preferred embodiment of the present invention.

### DETAILED DESCRIPTION OF THE INVENTION

Hereinafter, embodiments of the present invention will be described in detail with reference to the accompanying drawings so that those of ordinary skill in the art easily carry out the present invention. However, the present invention may be implemented in various different forms and should not be construed as being limited to the embodiments described herein. Some parts of the present invention are omitted in the drawings in order not to unnecessarily obscure the present invention. Like reference numerals refer to like elements throughout the description.

According to a white LED device of the present invention, an LED chip for emitting light with a peak wavelength of 440-560 nm and a phosphor for emitting light with a peak wavelength of about 560-670 nm are combined with each other so as to generate white light similar to natural light. Hereinafter, specific embodiments of the present invention will be described in detail with reference to the accompanying drawings.

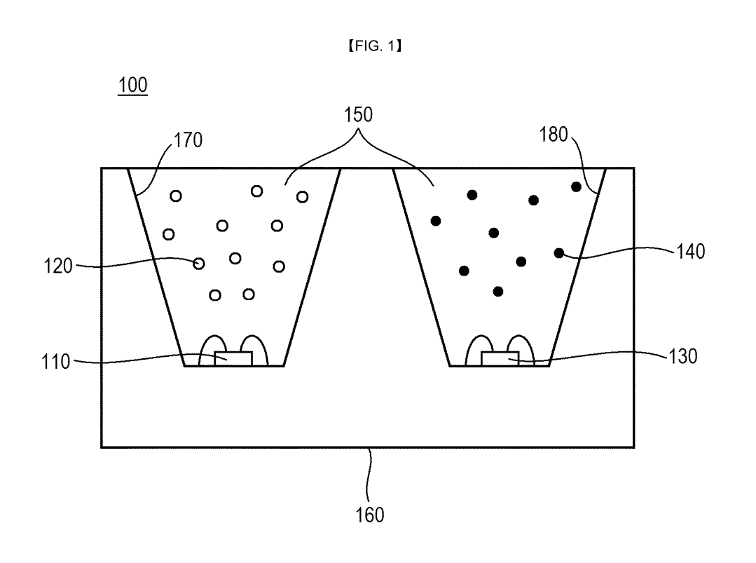

FIG. 1 is a vertical cross-sectional view of a white LED device according to a preferred embodiment of the present invention.

As illustrated in FIG. 1, a white LED device 100 according to the preferred embodiment of the present invention may include a blue LED chip 110, a yellow phosphor 120, a green LED chip 130, and a red phosphor 140.

In detail, the blue LED chip 110 emits blue light with a peak wavelength of about 440-490 nm, and the yellow phosphor 120 absorbs a part of the blue light emitted from the blue LED chip 110 and is excited, and then emits yellow light with a peak wavelength of about 560-615 nm.

The green LED chip 130 emits green light with a peak wavelength of about 500-560 nm, and the red phosphor 140 absorbs a part of the green light emitted from the green LED chip 130 and is excited, and then emits red light with a peak wavelength of about 615-670 nm.

The blue light and the green light respectively emitted from the blue LED chip 110 and the green LED chip 130, and the yellow light and the red light respectively emitted from the yellow phosphor 120 and the red phosphor 140 are mixed with one another so that white light is generated.

In this case, it is desirable that the blue LED chip 110 and the green LED chip 130 be surrounded by a mixture of light-transmitting resin 150 and the green phosphor 120 processed into a powder form and a mixture of the light-transmitting resin 150 and the red phosphor 140 so as to be excited by the blue light and the green light. Although the yellow phosphor 120 and the red phosphor 140 have powder forms herein, the phosphors are not limited thereto. It should be understood that the phosphors may be modified, as necessary, into various other forms such as a pellet or a layered structure.

Hereinafter, the white LED device according to the preferred embodiment of the present invention will be described in more detail with reference to the accompanying drawings.

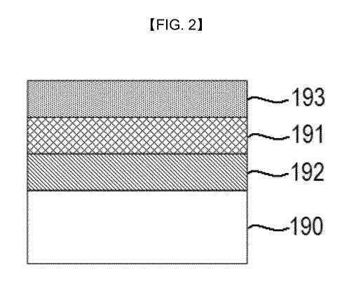

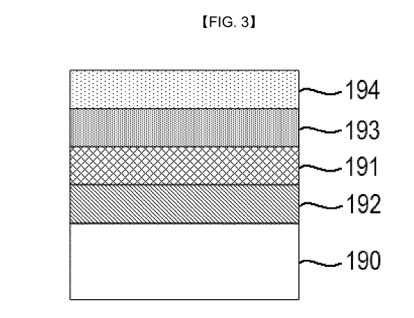

FIGS. 2 and 3 are vertical cross-sectional views of a layered structure of the white LED devices according to the preferred embodiment of the present invention.

The blue LED chip 110 and the green LED chip 130 may be manufactured using a nitride semiconductor such as AlInGaN. In detail, as illustrated in FIG. 2, a nitride LED chip of the present invention includes an active layer 191 for generating light, an n-type nitride layer 192 formed under the active layer 191 to provide electrons, and a p-type nitride layer 193 disposed on the active layer 191 to provide holes. Furthermore, reference numeral 190 represents a substrate in FIGS. 2 and 3.

In this case, as illustrated in FIG. 3, a p-type ZnO layer 194 doped with arsenic (As) may be deposited on the p-type nitride layer 193 so as to form a thin film structure. The p-type ZnO layer 194 provides holes to the active layer 191 where holes are insufficient in comparison with electrons, so as to increase light output. In particular, in the case of a green LED chip, external quantum efficiency (EQE) is less than about 30%, and light output is about 50% less than that of a blue LED chip at the same injection current. That is, it is known that the green LED chip has very low light efficiency in comparison with the blue LED chip or the red LED chip since holes are not sufficiently supplied from the p-type nitride layer to the active layer. The light output and the light efficiency of the green LED chip may be improved by depositing the p-type nitride layer on the green LED chip under the same process condition as that of the blue LED chip. However, since a depositing temperature is too high, an active layer for generating green light, e.g., a quantum well, may be destroyed.

Therefore, according to the present invention, the p-type ZnO layer 194 is deposited on the p-type nitride layer 193 as described above so as to additionally provide holes to the active layer 191, thereby stably improving the light output and the light efficiency of the green LED chip 130.

Another transparent oxide layer may be used instead of the p-type ZnO layer 194 provided that the transparent oxide layer has sufficient holes to be provided to the active layer 191 and has an excellent light transmittance. For example, a p-type BeZnO layer may be used as the transparent oxide layer. The use of the p-type BeZnO layer may bring about the same effect as that of the p-type ZnO layer 194. Furthermore, in order to form a high-quality ohmic contact to manufacture the white LED device 100, an indium tin oxide (ITO) with excellent transparency or a metal with excellent reflectivity may be deposited on the transparent oxide layer.

A YAG-based phosphor containing rare-earth elements such as Ce-doped (YGd)₅Al₅O₃ or a silicate-based phosphor such as Eu-doped Sr₃SiO₅ may be used as the yellow phosphor 120.

The red phosphor 140 may be selected, as appropriate, from a nitride-based phosphor containing rare-earth elements such as Eu-doped SrBaCaAlSiN₃, an oxide-based phosphor such as Eu-doped Y₂O₃, and a sulfide-based phosphor such as Eu-doped CaS.

In detail, LxMyN((2/3)x+(4/3)y):R or LxMyOzN((2/3)x+(4/3)y−(2/3)z):R (where, L is at least one type selected from group II elements consisting of Mg, Ca, Sr, Ba and Zn, M is at least one type selected from group IV elements essentially consisting of Si from among C, Si and Ge, R is at least one type selected from rare-earth elements essentially consisting of Eu from among Y, La, Ce, Pr, Nd, Sm, Eu, Gd, Tb, Dy, Ho, Er and Lu) may be used as the nitride-based phosphor. (6MgO)(As₂O₅):Mn, (3.5MgO)(0.5MgF₂)(GeO₂):Mn, Li₂TiO₃:Mn, or LiAlO₂:Mn may be used as the oxide-based phosphor. MS:Eu (where, M is at least one type selected from group II elements consisting of Mg, Ca, Sr, Ba, Zn and Cd) may be used as the sulfide-based phosphor.

The white LED device according to the preferred embodiment of the present invention has been described. Hereinafter, a white LED device according to another preferred embodiment of the present invention will be described in detail with reference to the accompanying drawings.

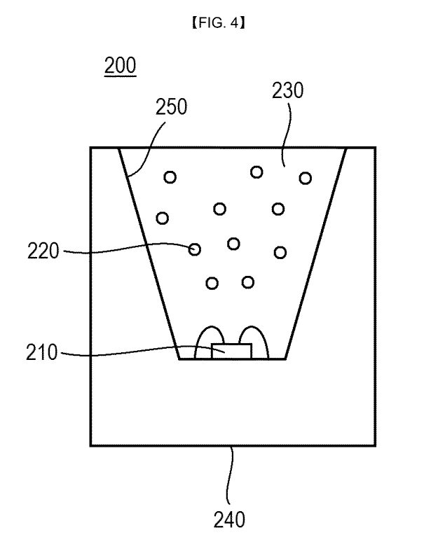

FIG. 4 is a vertical cross-sectional view of a white LED device according to another preferred embodiment of the present invention.

As illustrated in FIG. 4, a white LED device 200 according to the other preferred embodiment may include a bluish green LED chip 210 and a red phosphor 220.

In detail, the bluish green LED chip 210 emits bluish green light with a peak wavelength of about 490-550 nm, more specifically, about 500-520 nm, and the red phosphor 220 absorbs a part of the bluish green light emitted from the bluish green LED chip 210 and is excited, and then emits red light with a peak wavelength of about 590-670 nm, more specifically, about 630-655 nm.

When a current is applied to the white LED device 200 through an electrode, bluish green light is emitted from the bluish green LED chip 210, and a part of the bluish green light is absorbed by the red phosphor 220. When the part of the bluish green light is absorbed by the red phosphor 220, the red phosphor 220 is excited to emit red light. This red light and the unabsorbed bluish green light of the bluish green LED chip 210 are mixed with each other so as to emit whit light.

In this case, the red phosphor 220 processed into a powder form is mixed with a light-transmitting resin 230, and then surrounds the bluish green LED chip 210 so as to be excited by the bluish green light. Alternatively, the red phosphor 220 may be formed into a thin lump, i.e., a pellet, to be mixed with the light-transmitting resin 230 in a layered structure.

According to the present invention, the red phosphor 220 may be selected, as appropriate, from a nitride-based phosphor containing rare-earth elements (for example, Eu-doped SrBaCaAlSiN₃), an oxide-based phosphor (for example, Eu-doped Y₂O₃) and a sulfide-based phosphor (for example, Eu-doped CaS).

The bluish green LED chip 210 may be manufactured using a nitride semiconductor of AlInGaN. In detail, as described above with reference to FIG. 2, the bluish LED chip 210 may include an active layer 191 for generating light, an n-type nitride layer 192 for providing electrons to the active layer 191, and a p-type nitride layer 193 for providing holes to the active layer 191.

According to the present invention, as illustrated in FIG. 3, the p-type ZnO layer 194 doped with arsenic (As) may be deposited on the p-type nitride layer 193 so as to form a thin film structure. Due to the p-type ZnO layer 194, holes are additionally provided to the active layer 191, thereby improving light output. In this case, another transparent oxide layer, e.g., a p-type Be_{y}Zn_{1-y}O (0≦y≦1) layer doped with arsenic (As), may be used instead of the p-type ZnO layer 194 in order to achieve the same effect. Furthermore, in order to achieve a high-quality ohmic contact, an ITO with excellent transparency or a metal with excellent reflectivity may be deposited on the transparent oxide layer.

The white LED device according to the other preferred embodiment of the present invention has been described. Hereinafter, an installation method of the present invention will be described in detail.

Referring to FIG. 4, the bluish green LED chip 210 and the red phosphor 220 may be installed in a package body 240. In detail, a concave reflective cup 250 is formed in the inside of the package body 240, and the bluish LED chip 210 is mounted on a bottom surface of the reflective cup 250. The red phosphor 220 is accommodated in the reflective cup 250 together with the light-transmitting resin 230 so as to surround the bluish green LED chip 210 as described above. In this case, it is desirable that an inner circumferential surface of the reflective cup 250 be coated with a high reflective material in order to improve light reflectivity.

Herein, for convenience, an electrode pattern or a lead frame electrically connected to the LED chip is not illustrated in FIG. 4. Furthermore, although the installation method is described herein with respect to only the embodiment of FIG. 4, the installation method may also be applied to the embodiment of FIG. 1.

According to the present invention, in an alternative manner to the above-described method, the bluish green LED chip 210 and the red phosphor 220 may be directly mounted on a PCB substrate (not illustrated) using a chip on board (COB) technology. In this case, the red phosphor 220 is applied onto the bluish green LED chip 210 together with the light-transmitting resin using a mold.

The installation method of the white LED device according to the present invention has been described. Hereinafter, an operation and an effect of the present invention will be described.

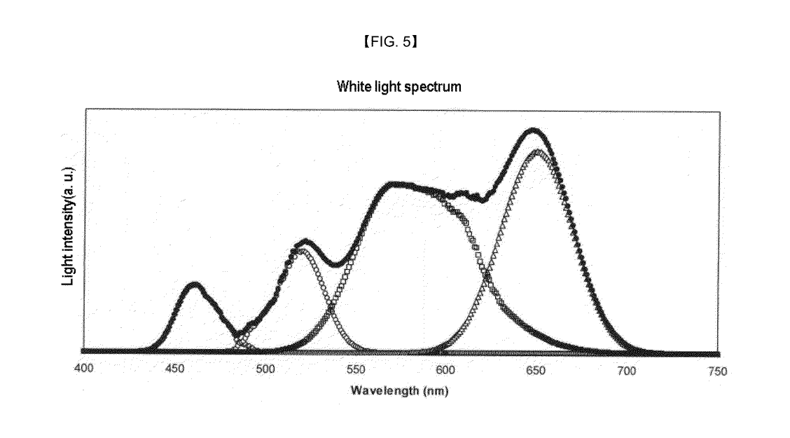

In order to check a color rendering property of the white LED device according to the preferred embodiment of the present invention, depending on a peak wavelength of the white LED device, a white light spectrum was measured while adjusting peak wavelengths of light emitted from LED chips and phosphors. A result of the measurement is shown in FIG. 5. As shown in FIG. 5, white light with an excellent color rendering property was obtained when a blue LED chip emitting light of a peak wavelength of about 450-475 nm, a green LED chip emitting light of a peak wavelength of about 525-535 nm, a yellow phosphor emitting light of a peak wavelength of about 560-580 nm, and a red phosphor emitting light of a peak wavelength of about 625-660 nm were used.

Furthermore, a correlated color temperature and a color rendering index of the white light emitted at the above-mentioned peak wavelength ranges were measured to be compared with those of a white LED manufactured using a YAG-based phosphor as shown in Table 1 below. Here, the correlated color temperature was measured using a known color temperature measurer, and the color rendering index was determined by measuring the spectrum of the white light and comparing the spectrum with a light emitting spectrum of a standard light source.

TABLE 1

| | Correlated | |
|---|---|---|
| | color temperature | Average color |
| Classification | (K) | rendering index |
| White LED using a | 5000-8300 | 65 |
| YAG-based phosphor | | |
| White LED according to the | 2500-7000 | at least 80 |
| present invention | | |

It may be confirmed that the white LED according to the present invention has a lower correlated color temperature and a higher color rendering index than those of the conventional white LED using the YAG-based phosphor from Table 1.

In addition, in order to check light efficiency of the present invention, external quantum efficiency of the green LED and light output thereof were measured to be compared with those of a conventional green LED as shown in Table 2.

TABLE 2

| | External | Light |
|---|---|---|
| | quantum efficiency | output (compared to a |
| Classification | (EQE) | blue LED) |
| Conventional green LED | Lower than 30% | Lower than 50% |
| Green LED according to | At least 35% | At least 60% |
| the present invention | | |

As shown in Table 2, the external quantum efficiency and the light output of the green LED according to the present invention have been remarkably improved in comparison with the conventional green LED. Therefore, according to the present invention, non-luminescent light output loss that occurs when a phosphor is excited is expected to be minimized, improving energy efficiency.

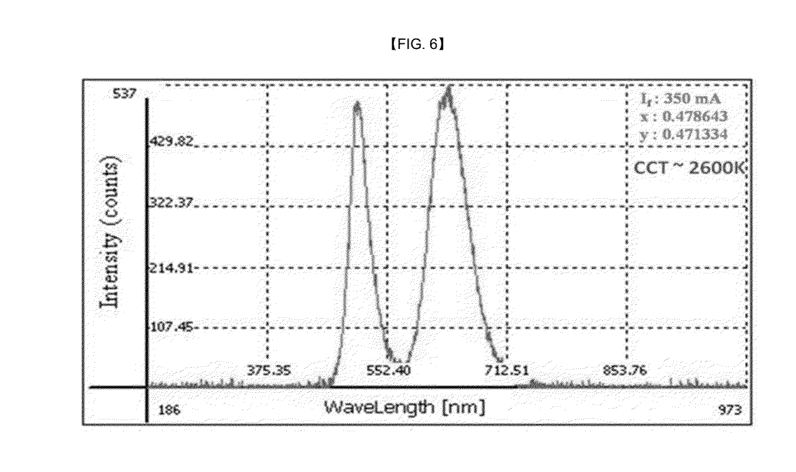

In order to check a color rendering property of the white LED device according to the other preferred embodiment of the present invention, a white light spectrum was measured while adjusting peak wavelengths of light emitted from LED chips and phosphors. A result of the measurement is shown in FIG. 6. As shown in FIG. 6, white light with an excellent color rendering property was obtained when a bluish green LED chip emitting light of a peak wavelength of about 500-520 nm and a red phosphor emitting light of a peak wavelength of about 590-670 nm were used.

Furthermore, a correlated color temperature and a color rendering index of the white light emitted at the above-mentioned peak wavelength ranges were measured as shown in Table 3 below.

TABLE 3

| | Correlated | |
|---|---|---|
| | color temperature | Average color rendering |
| Classification | (K) | index |
| White LED according to | 2000-3000 | At least 80 |
| the present invention | | |

It may be confirmed that the white LED according to the other preferred embodiment of the present invention has a lower correlated color temperature and a higher color rendering index than those of the conventional white LED from Table 3.

According to the present invention, high-quality white light, which has a color rendering index similar to that of natural light and a correlated color temperature of about 2000-7000 K and is suitable for emotional lighting, may be obtained using an LED chip and a phosphor emitting light of specific peak wavelength ranges.

Furthermore, since a red phosphor is excited using a high-efficiency green or bluish green LED chip, non-luminescent light output loss which occurs due to a stokes shift generated when the phosphor converts light color is minimized, and thus high energy efficiency may be obtained.

Moreover, by applying the present invention to indoor lighting, a residential environment may become more comfortable due to the improved color rendering index and the lower color temperature.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A white LED device comprising:
an LED chip configured to emit light with a peak wavelength range of about 440 nm to about 560 nm; and
a phosphor excited by the LED chip to emit light with a peak wavelength range of about 560 nm to about 670 nm.

2. The white LED device of claim 1, comprising:
a blue LED chip configured to emit blue light;
a yellow phosphor formed on the blue LED chip and excited by the blue light to emit yellow light;
a green LED chip configured to emit green light; and
a red phosphor formed on the green LED chip and excited by the green light to emit red light.

3. The white LED device of claim 1, comprising:
a bluish green LED chip configured to emit bluish green light; and
a red phosphor formed on the bluish green LED chip and excited by the bluish green light to emit red light.

4. The white LED device of claim 2, wherein the blue LED chip, the green LED chip, and the bluish green LED chip have a thin film structure in which a p-type transparent oxide layer is deposited on a p-type nitride layer.

5. The white LED device of claim 4, wherein the p-type transparent oxide layer is a p-type ZnO layer doped with arsenic or a p-type BeZnO layer doped with arsenic.

6. The white LED device of claim 2, wherein the yellow phosphor is a YAG-based phosphor or a silicate-based phosphor.

7. The white LED device of claim 2, wherein the red phosphor is at least one selected from a sulfide-based phosphor, a nitride-based phosphor, and an oxide-based phosphor.

8. The white LED device of claim 2, wherein the yellow phosphor and the red phosphor have a powder form, a pellet form, or a layered structure.

9. The white LED device of claim 2, further comprising:
a reflective cup accommodating the LED chip and the phosphor; and
a package body in which the reflective cup is installed.

10. The white LED device of claim 2, further comprising:
a PCB substrate on which the LED chip is mounted, wherein the phosphor is applied onto the LED chip using a mold.
